(19) United States
(12) Patent Application Publication
(10) Pub. No.: US 2013/0244429 A1
(43) Pub. Date: Sep. 19, 2013

(54) SHOT BLASTING MATERIAL USED FOR SILICON SUBSTRATE SURFACE TREATMENT AND METHOD FOR PREPARING SILICON SUBSTRATE

(71) Applicants: Dandan Wan, Shanghai (CN); Fei Wang, Shanghai (CN); Maria Fabra-Puchol, Shanghai (CN)

(72) Inventors: Dandan Wan, Shanghai (CN); Fei Wang, Shanghai (CN); Maria Fabra-Puchol, Shanghai (CN)

(73) Assignees: Saint-Gobain Ceramic Materials (Mudanjiang) Co., Ltd., Heilongjiang (CN); Saint-Gobain Research (Shanghai) Co., Ltd., Shanghai (CN)

(21) Appl. No.: 13/884,804

(22) PCT Filed: Aug. 15, 2012
(86) PCT No.: PCT/CN2012/080164

§ 371 Date: May 10, 2013

(30) Foreign Application Priority Data
Aug. 23, 2011 (CN) 201110243364.9
Aug. 23, 2011 (CN) 201110243546.6

(51) Int. Cl. H01L 31/0236

(52) U.S. Cl. CPC H01L 31/02366
USPC 438/691; 51/307

(57) ABSTRACT

A shot blasting material used for silicon substrate surface treatment and a method for preparing a silicon substrate. The shot blasting material includes silicon carbide particles, and the median particle diameter of the silicon carbide particles is 1 μm to 30 μm. Surface treatment can be performed on at least one surface of a silicon substrate in a bombarding manner through the shot blasting material. The particle diameter of the silicon carbide particles used for bombarding is small, and only a mechanical damage layer with a small thickness is formed on a first surface of the silicon substrate, so in the subsequent chemical treatment procedure, it is not required to add concentrated sulfuric acid to a chemical corrosive liquid, and a corrosion step and a cleaning step may be combined into one step, thereby reducing the process flow time, and decreasing the process cost; meanwhile, the method is environment friendly.

### CROSS-REFERENCE TO RELATED APPLICATIONS

The present application claims priority to Chinese patent application No. 201110243364.9, filed on Aug. 23, 2011, and entitled “METHOD FOR PRODUCING SILICON SUBSTRATE”, and Chinese patent application No. 201110243546.6, filed on Aug. 23, 2011, and entitled “BLASTING MATERIAL ADAPTED TO BLAST SURFACE OF SILICON SUBSTRATE AND SILICON SUBSTRATE”, and the entire disclosures of which are incorporated herein by reference.

### FIELD OF THE DISCLOSURE

The present disclosure generally relates to silicon substrate processing technology, and more particularly, to a blasting material adapted to blast a surface of a silicon substrate and a method for producing a silicon substrate.

### BACKGROUND OF THE DISCLOSURE

Silicon solar cells apply silicon sheets as substrates. A solar cell may have a surface facing and being irradiated by the sun lights, so that solar lights may be absorbed and transformed into electrical power by the solar cell. The electrical power, transformed from the solar lights absorbed from the surface of the solar cell, is output as current through the solar cell's positive and negative electrodes, and further be provided to a device or apparatus needing electrical power.

An important approach for improving the photoelectrical conversion rate of the solar cell is to reduce the light reflectivity of the solar cell's surface which faces the sun lights, which may be effectively achieved by forming a rough textured surface.

Chinese patent application No. 200510029562.X (hereinafter refer to as '562 Application) discloses a method for forming a textured surface for a silicon substrate, including following steps:

Step 1, blasting a surface of a silicon substrate with SiC particles having an average granularity of 300 mesh under a pressure ranging from about 1 kg to about 3 kg, to remove some films on the surface of the silicon substrate. These films may be, for instance, SiN films, TiN films, or SiC films. After the blasting, a defected silicon layer is exposed, and the silicon substrate is formed to have a rough surface with a roughness greater than about 0.3 μm, while another surface of the silicon substrate opposite to the blasted surface remains smooth.

Step 2, dipping the silicon substrate having the rough surface into an acid corrosion solution. After the corrosion treatment, the silicon substrate has a more textured surface, while the opposite surface remains smooth. The textured structure has a thickness within a range from about 6 μm to about 8 μm.

Step 3, cleaning the silicon substrate with a mixed solution including 5% (mass percentage) HF, 5% (mass percentage) HCl and 90% (mass percentage) pure water for 5 minutes, where the mass percentage of HF is 5±1%, the mass percentage of HCl is 5±1%, and the rest is pure water.

Specifically, conditions for the acid corrosion treatment in Step 2 include:

1. Composition of the acid corrosion solution (mass percentage):

ionic compound including cations of Na, K or Li, and anions of nitrate or nitrite, or ionic compound including cations of Na, K or Li, and anions of permanganate, 3% to 20%;

nitrite ions including NH₄⁺ and K, or Na, K, or Li, 3% to 10%; and 60% to 96% sulfuric acid.

Or else, the composition of the acid corrosion solution (mass percentage) may be: solid KNO₃, 5%; solid NH₄HF₂, 5%; and 70% sulfuric acid, 90%.

Or else, the composition of the acid corrosion solution (mass percentage) may be: solid KNO₃, 10%; solid NH₄HF₂, 10%; and 96% sulfuric acid, 80%.

Or else, the composition of the acid corrosion solution (mass percentage) may be: solid KNO₃, 3%; solid NH₄HF₂, 3%; and 96% sulfuric acid, 94%.

2. Treatment temperature: 0° C. to room temperature; and

3. Corrosion time: depending on the silicon substrate's thickness required by users.

However, the SiC particles used in the solution disclosed in '562 Application have a relatively large granularity, which requires the silicon substrate to have high thickness and intensity. The solution may only be suitable for treating silicon substrates which are relatively thick and obtained by slicing silicon ingots. Such silicon substrates may inevitably have mechanical damages on both sides thereof. If the SiC particles applied in the solution are relatively large in granularity, the mechanical damage layer resulted from the blasting may be especially large in thickness. An over-thick mechanical layer, on one hand, is an unnecessary waste of expensive silicon materials, which may increase production costs, on the other hand, may adversely affect subsequent treatment. In subsequent treatment, it is desired that the mechanical damage layer is removed as much as possible while a surface with relatively low reflection rate is achieved. Therefore, the excessive mechanical damage layer produced in '562 application needs to be removed by an acid corrosion treatment involving concentrated sulfuric acid. However, H₂O may be generated during the corrosion treatment involving concentrated sulfuric acid, which may change the concentration of the solution. As a result, a new solution is required after a certain amount of silicon substrates are treated, which increases the production costs and is not friendly to environment.

### SUMMARY

A blasting material adapted to blast a surface of a silicon substrate and a method for producing a silicon substrate are provided. The method may not only be used to process relatively thick silicon substrates sliced from silicon ingots and with relatively high intensity, but also be used to process relatively thin silicon substrates which have relatively low intensity and substantially no mechanical damages. The process time and consumption of chemical corrosion solution may be reduced, thereby reducing the production costs of solar cells.

The blasting material adapted to blast a surface of a silicon substrate may include SiC particles with a median particle diameter within a range from about 1 μm to about 30 μm.

Optionally, the median particle diameter may be within a range from about 6 μm to about 30 μm.

Optionally, the median particle diameter may be within a range from about 10 μm to about 20 μm.

Optionally, the median particle diameter may be within a range from about 6 μm to about 10 μm.

Optionally, the SiC particles may have an average sphericity within a range from about 0.80 to about 0.94.

Optionally, the SiC particles may have an average sphericity within a range from about 0.80 to about 0.92.

Optionally, the SiC particles may include hexagonal SiC particles.

Optionally, a weight percentage of the hexagonal SiC particles relative to the SiC particles may be within a range from about 70% to about 100%.

A method for producing a silicon substrate using the blasting material is further provided. The method may include: providing a silicon raw piece, wherein the silicon raw piece includes a first surface and a second surface opposite to the first surface; and blasting the first surface of the silicon raw piece with the SiC particles to form a mechanical damage layer having a third surface.

Optionally, the silicon raw piece may have a thickness within a range from about 120 μm to about 200 μm.

Optionally, the silicon raw piece may have a thickness within a range from about 160 μm to about 190 μm.

Optionally, the method may further include: partially removing the mechanical damage layer by conducting chemical treatment to the third surface so as to achieve the silicon substrate.

Optionally, the mechanical damage layer may have a thickness within a range from about 3 μm to about 10 μm.

Optionally, the mechanical damage layer may have a thickness within a range from about 4 μm to about 8 μm.

Optionally, the mechanical damage layer may include a particle embedding layer, a mechanical layer, a stress layer and a crystalline defect layer positioned from outside to inside in sequence, wherein the particle embedding layer locates at the outermost surface of the silicon substrate.

Optionally, the third surface may have a reflectivity within a range from about 25% to about 30%.

Optionally, a ten point height of irregularities Rz of the third surface may be within a range from about 2 μm to about 4 μm.

Optionally, a ten point height of irregularities Rz of the third surface may be within a range from about 2 μm to about 2.5 μm.

Optionally, the method may further include: substantially removing the entirety of the particle embedding layer, the mechanical layer and the stress layer in the mechanical damage layer and partially removing the crystalline defect layer from the mechanical damage layer, by conducting chemical treatment to the third surface.

Optionally, the mechanical damage layer may be partially removed by conducting chemical treatment to the third surface, wherein the remaining mechanical damage layer may have a thickness less than 2 μm.

Optionally, the silicon substrate may be adapted for a silicon solar cell having a light receiving surface, and the method may further include: partially removing the mechanical damage layer by conducting chemical treatment to the third surface so as to achieve the silicon substrate, wherein the silicon substrate may have a fourth surface corresponding to the light receiving surface of the silicon solar cell, and a reflectivity of the fourth surface may be lower than the reflectivity of the third surface.

Optionally, the chemical treatment may include etching the third surface with an acid solution.

Optionally, the acid solution may be a mixed solution of HNO₃, HF and deionized water, or a mixed solution of HNO₃, HF and C₂H₄O₂.

Optionally, the HNO₃ together with the HF may have a volume concentration in the acid solution within a range from about 5% to about 20%, the deionized water may have a volume concentration in the acid solution within a range from about 95% to about 80%, and a volume ratio of the HF to the HNO₃ may be within a range from about 1 to about 15.

Optionally, the HNO₃ together with the HF may have a volume concentration in the acid solution within a range from about 5% to about 20%, the C₂H₄O₂ may have a volume concentration in the acid solution within a range from about 95% to about 80%, and a volume ratio of the HF to the HNO₃ may be within a range from about 1 to about 15.

Optionally, a ten point height of irregularities Rz of the fourth surface achieved after conducting the chemical treatment may be greater than a ten point height of irregularities Rz of the third surface achieved after conducting the blasting treatment.

Optionally, the first surface of the silicon raw piece may have a reflectivity within a range from about 30% to about 40%.

Optionally, the third surface may have a reflectivity within a range from about 25% to about 30%.

Optionally, the method may further include: partially removing the mechanical damage layer so as to achieve the silicon substrate having a fourth surface by conducting chemical treatment to the third surface, wherein a reflectivity of the fourth surface is lower than the reflectivity of the third surface.

Optionally, the third layer may have a thickness within a range from about 3 μm to about 10 μm.

Optionally, the method may further include: partially removing the mechanical damage layer so as to achieve the silicon substrate by conducting chemical treatment to the third surface, wherein the remaining mechanical damage layer has a thickness less than 2.5 μm.

Optionally, a ten point height of irregularities Rz of the first surface may be less than 0.5 μm.

Optionally, a ten point height of irregularities Rz of the third surface may be within a range from 2 μm to about 4 μm.

Optionally, the method may further include: achieving the silicon substrate having a fourth surface by conducting chemical treatment to the third surface, wherein a ten point height of irregularities Rz of the fourth surface is greater than the ten point height of irregularities Rz of the third surface.

Optionally, the method may further include: partially removing the mechanical damage layer so as to achieve the silicon substrate having a fourth surface by conducting chemical treatment to the third surface with a mixed acid solution of HNO₃, HF and deionized water, or a mixed acid solution of HNO₃, HF and C₂H₄O₂.

The blasting material adapted to blast a surface of a silicon substrate has a relatively small particle diameter. As a result, a first surface of the silicon substrate is formed to have a mechanical damage layer only with a small thickness during blasting treatment. A silicon raw piece produced by a crystal ribbon method has almost no mechanical damage layer formed on both two sides thereof. Therefore, when blasting treatment is conducted to the silicon raw piece produced by the crystal ribbon method, the effect is particularly obvious. Therefore, in subsequent chemical treatment, it is not necessary to use concentrated sulfuric acid for dipping and corrosion. An acid solution made of HNO₃, HF and deionized water (or C₂H₄O₂) is applicable for the dipping and corrosion. H₂O may be generated during corrosion treatment involving concentrated sulfuric acid, which may change the concentration of the solution. As a result, a new solution is required after about 16 thousands silicon substrates are treated. In the present disclosure, the acid solution used in the chemical treatment may tread over 300 thousands silicon substrates continuously. Besides, a corrosion step and a cleaning step can be combined into one step. Therefore, the present disclosure reduces process time and cost and is friendly to environment.

### BRIEF DESCRIPTION OF THE DRAWINGS

FIG. 1 schematically illustrates a flow chart of a first method for producing a silicon substrate using a blasting material according to one embodiment of the present disclosure;

FIG. 2 schematically illustrates a flow chart of a second method for producing a silicon substrate using a blasting material according to one embodiment of the present disclosure;

FIG. 3 schematically illustrates a cross-sectional view of a silicon substrate blasted using a blasting material according to one embodiment of the present disclosure; and

FIG. 4 schematically illustrates a cross-sectional view of a silicon substrate which is blasted using a blasting material and chemically processed according to one embodiment of the present disclosure.

### DETAILED DESCRIPTION OF THE DISCLOSURE

Methods for blasting a surface of a silicon substrate of the present disclosure will be described in detail in conjunction with specific embodiments.

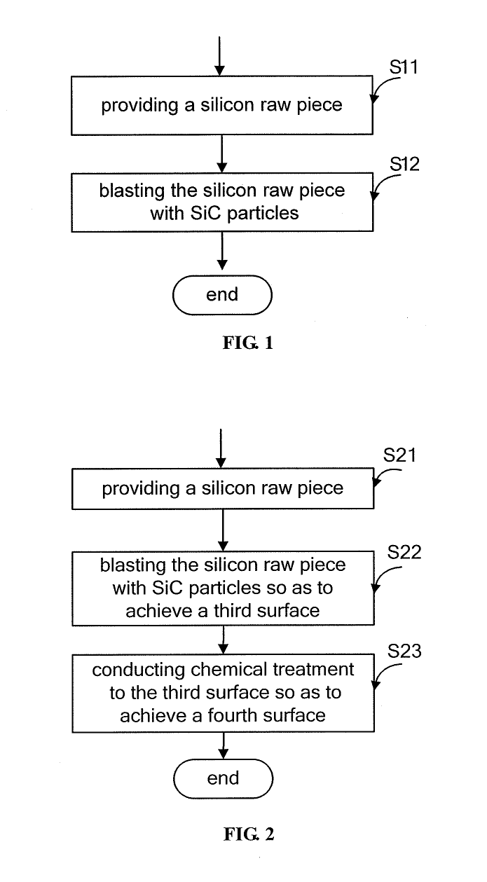

FIG. 1 schematically illustrates a flow chart of a first method for producing a silicon substrate using a blasting material according to one embodiment of the present disclosure. The first method may include steps of S11 and S12.

Step S11, providing a silicon raw piece.

A silicon raw piece is provided, which includes a first surface and a second surface opposite to the first surface.

Step S12, blasting the silicon raw piece with SiC particles.

The first surface of the silicon raw piece is blasted with SiC particles, so that a mechanical damage layer is formed, having a third surface.

The SiC particles have a median particle diameter within a range from about 1 μm to about 30 μm.

FIG. 2 schematically illustrates a flow chart of a second method for producing a silicon substrate using a blasting material according to one embodiment of the present disclosure. The second method may include steps of S21, S22 and S23.

Step S21, providing a silicon raw piece.

A silicon raw piece is provided, which includes a first surface and a second surface opposite to the first surface.

Step S22, blasting the silicon raw piece with SiC particles so as to achieve a third surface.

The first surface of the silicon raw piece is blasted with SiC particles, so that a mechanical damage layer is formed, having a third surface.

The SiC particles have a median particle diameter within a range from about 1 μm to about 30 μm.

Step S23, conducting chemical treatment to the third surface, so as to achieve a fourth surface.

Chemical treatment is conducted to the third surface, so that the mechanical damage layer is partially removed, and the silicon substrate is thereby achieved, having a fourth surface.

In some embodiments, the silicon raw piece may be produced by applying a crystal ribbon method. The crystal ribbon method uses directional solidification technology of polycrystalline silicon, including: Edge defined Film-fed Growth (EFG), String Ribbon Growth (SRG), Ribbon Growth on Substrate (RGS), Silicon Sheets from Powder (SSP) and Dendritic Web Growth (DWG).

In the crystal ribbon method, the silicon raw piece is formed without being sliced or affected by external forces, but only grows with pull up. Therefore, the silicon raw piece may have almost no mechanical damage layer. The silicon raw piece produced by the crystal ribbon method may have a thickness within a range from about 120 μm to about 200 μm, and a surface reflectivity within a range from about 30% to about 40%. Compared with a piece sliced from an ingot, the silicon raw piece produced by the crystal ribbon method is formed directly, without a slicing process, so that the raw material utilization is improved. It should be noted that, although the silicon raw piece is preferably formed by using the crystal ribbon method, the present disclosure should not be limited thereto. In other embodiments, the silicon raw piece may be produced with other methods, such as silicon ingot slicing. A silicon raw piece produced by other methods can also be blasted with a blasting material of the present disclosure.

Blasting the silicon raw piece means performing abrasive blasting on the silicon raw piece with a blasting device.

The blasting device may employ compressed air as motive power to form a high-speed blasting particle beam. The high-speed blasting particle beam may be delivered, through a nozzle, to a first surface of the silicon raw piece to be treated, so that a change occurs in mechanical performance of the first surface. The blasting device may include a nozzle and a conveying apparatus. The conveying apparatus is an apparatus which can move relatively to the nozzle and is adapted to place the silicon raw piece to be treated, such as a conveying belt.

The reflectivity denotes to a reflectivity under solar spectrum with a wavelength within a range from about 300 nm to about 1100 nm.

Blasting the silicon raw piece is to form the first surface of the silicon raw piece to have a mechanical damage layer. Therefore, physical parameters of the SiC particles used in the blasting, such as median particle diameter, sphericity and crystal structure, are significant.

In some embodiments, “median particle diameter” is adopted to describe the particle diameter of the SiC particles, where 50% of the SiC particles have particle diameters greater than the median particle diameter, and the other 50% of the SiC particles have particle diameters less than the median particle diameter. In practice, if the SiC particles used for blasting a surface of a silicon substrate have large particle diameters, the blasted surface may have a relatively low surface roughness and may be formed to have a very large mechanical damage layer during the blasting treatment, or even be smashed, which, therefore, is not a desired processing result. However, if the SiC particles used for blasting the surface of the silicon substrate have too small particle parameters, a rough surface of the silicon substrate is hardly to be formed and the surface blasting efficiency may be very low. Furthermore, the SiC particles with undersized particle diameters are easily to be affected by an air flow during blasting, which may cause a blasting angle deviation and further affect the surface roughness of the blasted surface achieved after conducting the blasting treatment. Consequently, an appropriate range of the particle diameters is a key parameter for the blasting effect.

“Sphericity” denotes to the level of similarity of the SiC particles to a sphere. An average sphericity denotes an average value of the sphericities of the SiC particles within a random sampling range. SiC particles with a small sphericity may have sharp corners so that a rough surface of the silicon substrate is easy to be formed, thereby achieving a high surface blasting efficiency. Spheric particles with no corners are not likely to form a rough surface of the silicon substrate, only forming mechanical damage structures, which may affect the blasting effect. Consequently, an appropriate range of the sphericity is a key parameter for the blasting effect as well.

The sphericity may be measured using the flat particle flow principle. When measuring the sphericity, all particles of a sample may be disposed on a same focus layer, having largest surfaces thereof always facing a camera. A corresponding approach for calculating the sphericity of the particles is illustrated as follows: dividing a circumferential length of a circle with an area equal to that of a largest projection surface of the particles by a summation of practical circumferential lengths of the particles. The higher the level of similarity is, the closer the sphericity is to 1; the slenderer or the rougher the particle is, the less the sphericity may be.

There are various kinds of SiC particles. SiC particles with different crystal structures may have different performance. SiC mainly have two crystalline forms, α-SiC and β-SiC. α-SiC is a high temperature structure of SiC and belongs to a hexagonal crystalline type. α-SiC may have multiple variants, such as 6H, 4H, 15R, and the like. β-SiC belongs to a cubic crystalline type, where Si and C form face centered cubic lattices and β-SiC may transform to be α-SiC at a temperature over 2100□. α-SiC may be divided into two general basic types, being green SiC (having more than 99% SiC therein) and black SiC (having about 98.5% SiC therein) respectively. Since the hardness of either green SiC or black SiC is between that of corundum and that of diamond, both the green SiC and the black SiC may be adapted to blast a silicon substrate to increase the roughness of a surface of the silicon substrate. However, compared with black SiC, green SiC has a higher self-sharpening characteristic, so that a higher blasting efficiency may be achieved by using green SiC.

During the blasting treatment, many treatment parameters, such as compressed air pressure, blasting time, distance between the nozzle and the silicon substrate and blasting angle, are significant for forming a textured structure.

The compressed air pressure denotes to a value of compressed air pressure when blasting particles are blasted by a blasting machine. If the compressed air pressure is too large, wear and tear of the blasting machine may increase and the silicon substrate is more likely to break. In addition, the mechanical damage layer may have an undesired large thickness. If the compressed air pressure is too small, the blasting efficiency may reduce and the mechanical damage layer achieved after conducting the blasting treatment may not meet processing requirements. Consequently, during the blasting treatment, the compressed air pressure is a key parameter to influence the blasting efficiency.

The blasting time denotes to a time of the silicon substrate being blasted by high-speed SiC particles. The blasting time may be altered by adjusting blasting machine parameters, such as oscillation frequency of the nozzle and moving speed of the conveying belt (speed of blasting displacement). If the blasting time is too long, a surface of the silicon substrate may be formed to have a mechanical damage layer with an oversize thickness; if the blasting time is too short, a rough surface of the silicon substrate with desired roughness is hardly to be formed. Consequently, during the blasting treatment, the blasting time is a key parameter to influence the blasting efficiency.

The distance between the nozzle and the silicon substrate denotes to a vertical distance between the nozzle and a surface of the silicon substrate to be blasted. If the distance is too long, scattering of the blasting particles may be enlarged and blasting energy thereof may be reduced, so that a necessary rough surface is hardly to be formed and the blasting efficiency may be reduced as well. If the distance is too short, blasting energy may be over large and the silicon substrate is more likely to be broken, so that the blasting efficiency may be not acceptable. Consequently, during the blasting treatment, the distance between the nozzle and the silicon substrate is a key parameter to influence the blasting efficiency.

The blasting angle denotes to an angle between the nozzle and the surface of the silicon substrate. During a process of blasting a silicon substrate produced by using the crystal ribbon method, an undersized blasting angle may cause an increase on the damage rate of the silicon substrate. Consequently, the blasting angle is a key parameter to influence the blasting efficiency.

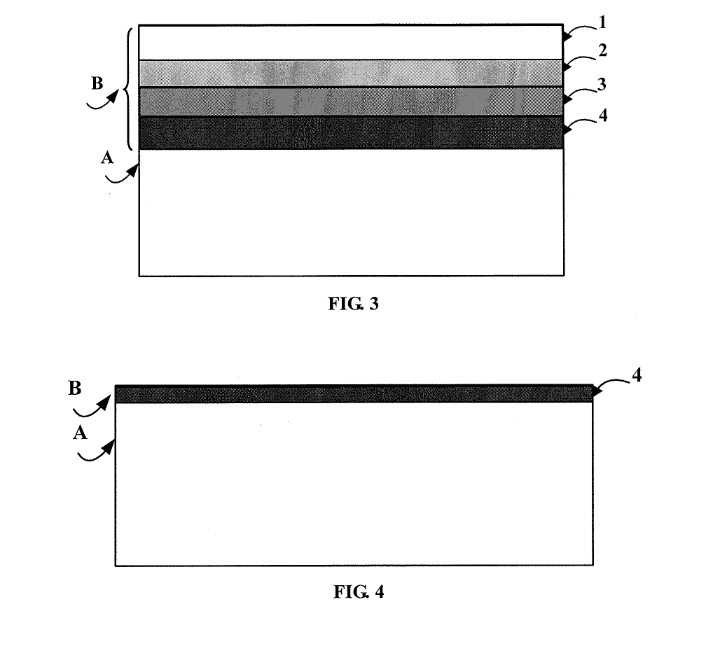

FIG. 3 schematically illustrates a cross-sectional view of a silicon substrate blasted using a blasting material according to one embodiment of the present disclosure.

The silicon substrate achieved after conducting blasting treatment may include a silicon substrate main body A and a mechanical damage layer B on the silicon substrate main body A. The mechanical damage layer B has a third surface.

The third surface is corresponding to a first surface of the silicon substrate before conducting the blasting treatment.

The mechanical damage layer B is a surface structure with a specific roughness formed in the silicon substrate achieved after conducting the blasting treatment with SiC particles, including a particle embedding layer 1, a mechanical layer 2, a stress layer 3 and a crystalline defect layer 4. The particle embedding layer 1 is distributed on an external surface of the mechanical damage layer B and the crystalline defect layer 4 is distributed on an inner surface of the mechanical damage layer B.

Generally, the surface roughness of the mechanical damage layer is denoted using there parameters, including Rmax (a maximum height of profile), Rz (a ten point height of irregularities) and Ra (an arithmetical mean deviation of profile).

The Rmax, namely, the maximum height of profile, denotes to a distance between a first horizontal line through the top of the profile and a second horizontal line through the bottom of the profile within a sampling length range.

The Rz, namely, the ten point height of irregularities, denotes to a sum of a mean value of five largest peak heights of the profile and a mean value of five largest valley heights of the profile within the sampling length range.

The Ra, namely, the arithmetical mean deviation of the profile, denotes to an arithmetical mean value of absolute values of distances between points on the profile and a base line in a direction of measurement within the sampling length range.

The mechanical damage layer achieved by conducting the blasting treatment to the first surface of the silicon substrate may have a surface roughness, thereby increasing the light absorbing area and reducing the light reflectivity. However, the mechanical damage layer may have a reverse influence on the performance of the silicon substrate. Consequently, after the blasting treatment, a chemical corrosion step may be performed to partially remove the mechanical damage layer.

FIG. 4 schematically illustrates a cross-sectional view of a silicon substrate which is blasted using a blasting material and chemically processed according to one embodiment of the present disclosure. The silicon substrate achieved after conducting the blasting treatment has a non-uniform surface, so that the mechanical damage layer may be partially removed after conducting chemical corrosion treatment, forming a fourth surface. The chemical corrosion treatment applies an acid solution mixed with HNO₃, HF and deionized water. Specifically, the particle embedding layer 1, the mechanical layer 2 and the stress layer 3 are completely removed, and the crystalline defect layer 4 may be partially removed, forming a textured structure. The fourth surface may have a light reflectivity lower than that of the third surface. Therefore, the efficiency of a final cell assembly may be improved by employing the chemical treatment according to embodiments of the present disclosure.

### Exemplary Embodiment One

A blasting material adapted to blast a surface of a silicon substrate is provided. The blasting material may include SiC particles. The blasting material may be used to blast the surface of the silicon substrate in a method described hereinafter. The method may include steps of:

Step 1: providing a silicon raw piece. The silicon raw piece is produced by applying a crystal ribbon method and includes a first surface and a second surface opposite to the first surface; and the first surface and the second surface substantially have almost no mechanical damage layer. Other physical parameters of the silicon raw piece may include:

a thickness of 170 μm; and

a surface reflectivity of 37.59%.

Step 2: under the action of compressed air, blasting the first surface of the silicon raw piece with the SiC particles.

1. Physical parameters of the SiC particles in the blasting material may include:

a median particle diameter of 16.260 μm;

an average sphericity of 0.872; and

a composition (weight percentage) of hexagonal SiC of 94.3%.

2. Treatment parameters of the blasting treatment may include:

a compressed air pressure of 3 bars;

a blasting time of 10 seconds (a blasting frequency of 35 Hz and a speed of blasting displacement of 600 mm/min);

a distance between a nozzle and the silicon substrate of 6 centimeters; and

a blasting angle of 90°.

The silicon substrate achieved after conducting the blasting treatment includes: a silicon substrate main body and a mechanical damage layer with a third surface on the silicon substrate main body. The third surface is corresponding to the first surface before conducting the blasting treatment. The thickness, surface roughness and average reflectivity of the formed mechanical damage layer are measured as follows.

The thickness of the mechanical damage layer is within a range from about 3 μm to about 10 μm.

The surface roughness includes:

A first group: Rmax of 2.51 μm, Rz of 2.1 μm and Ra of 0.261 μm;

A second group: Rmax of 2.25 μm, Rz of 2.03 μm and Ra of 0.272 μm;

A third group: Rmax of 2.45 μm, Rz of 2.21 μm and Ra of 0.294 μm; and

A fourth group: Rmax of 2.71 μm, Rz of 2.44 μm and Ra of 0.294 μm.

The average reflectivity is 27.26%.

Step 3: dipping and corroding the third surface with an acid solution.

1. composition of the corrosion solution (volume ratio)

mixing 65% HNO₃ (volume percent), 40% HF (volume percent) and deionized water to obtain the acid corrosion solution,

wherein HNO₃:HF:deionized water=1:1:5

2. dipping time: 2 minutes to 5 minutes

3. treatment temperature: room temperature

The silicon substrate achieved after the dipping includes a silicon substrate main body and a crystalline defect layer with a fourth surface on the silicon substrate main body, where the fourth surface is corresponding to the third surface before the dipping. Parameters of the silicon substrate include:

a thickness of the crystalline defect layer less than 2 μm;

a surface roughness Rz of the silicon substrate of 1.7 μm; and

an average reflectivity less than 25%.

A silicon substrate formed using conventional techniques may have a roughness of: Rmax of 1.88 μm, Rz of 1.71 μm and Ra of 0.256 μm. And a corresponding average reflectivity thereof is 26.43%.

Compared with the conventional techniques, the average reflectivity of the silicon substrate achieved after conducting the blasting treatment with the blasting material of the present disclosure is decreased by about 3.16%, while blasting treatment steps and production cycle are reduced. Furthermore, in some embodiments, no chemical corrosion solution needs to be consumed. Therefore, the present disclosure reduces production costs of a solar battery and is friendly to environment. It should be noted that, the silicon substrate achieved after conducting the blasting treatment but without conducting an extra chemical corrosion step may already meet the application requirements. However, to achieve a better effect, preferably, chemical corrosion treatment may be conducted to the silicon substrate achieved after conducting the blasting treatment.

By conducting the chemical treatment to the silicon substrate, the reflectivity thereof may be further reduced and a better effect may be achieved. Besides, the silicon raw piece produced by the crystal ribbon method has almost no mechanical damage layer formed on both two sides thereof. The SiC particles used for blasting have a relatively small particle diameter, so that, from the first surface of the silicon substrate, the mechanical damage layer is formed only with a small thickness and from the second surface, there is almost substantially no mechanical damage layer. Therefore, it is not necessary to use concentrated sulfuric acid for dipping and corrosion, since an acid solution made of HNO₃, HF and deionized water (or C₂H₄O₂) may be applicable. In the prior art, H₂O may be generated during corrosion treatment involving concentrated sulfuric acid, which may change the concentration of the solution. As a result, a new solution is required after about 16 thousands silicon substrates are treated. In the present disclosure, the acid solution used in the chemical treatment may treat over 300 thousands silicon substrates continuously. Besides, the corrosion step can also function as a cleaning step. Therefore, the present disclosure reduces processing time and cost and is friendly to environment.

### Exemplary Embodiment Two

A blasting material adapted to blast a surface of a silicon substrate is provided. The blasting material may include SiC particles. The blasting material may be used to blast the surface of the silicon substrate in a method described hereinafter. The method may include steps of:

Step 1: providing a silicon raw piece. The silicon raw piece is produced by applying a crystal ribbon method and includes a first surface and a second surface opposite to the first surface; and the first surface and the second surface substantially have almost no mechanical damage layer. Other physical parameters of the silicon raw piece may include:

a thickness of 170 μm; and

a surface reflectivity of 37.59%.

Step 2: under the action of compressed air, blasting the first surface of the silicon raw piece with the SiC particles.

1. Physical parameters of the SiC particles in the blasting material may include:

a median particle diameter of 16.260 μm;

an average sphericity of 0.872; and

a composition (weight percentage) of hexagonal SiC of 94.3%.

2. Treatment parameters of blasting treatment may include:

a compressed air pressure of 3 bars;

a blasting time of 12 seconds (a blasting frequency of 20 Hz and a speed of a blasting displacement of 400 mm/min);

a distance between a nozzle and the silicon substrate of 6 centimeters; and

a blasting angle of 90°.

The silicon substrate achieved after conducting the blasting treatment includes: a silicon substrate main body and a mechanical damage layer with a third surface on the silicon substrate main body. The third surface is corresponding to the first surface before conducting the blasting treatment. The thickness, surface roughness and average reflectivity of the formed mechanical damage layer are measured as follows.

The thickness of the mechanical damage layer is within a range from about 3 μm to about 10 μm.

The surface roughness includes:

A first group: Rmax of 2.39 μm, Rz of 2.09 μm and Ra of 0.296 μm;

A second group: Rmax of 2.22 μm, Rz of 2.00 μm and Ra of 0.278 μm;

A third group: Rmax of 2.58 μm, Rz of 2.31 μm and Ra of 0.297 μm; and

A fourth group: Rmax of 3.08 μm, Rz of 2.49 μm and Ra of 0.300 μm.

The average reflectivity is 28.17%.

Step 3: dipping and corroding the third surface with an acid solution.

1. composition of the corrosion solution (volume ratio)

mixing 65% HNO₃ (volume percent), 40% HF (volume percent) and deionized water to obtain the acid corrosion solution,

wherein HNO₃:HF:deionized water=1:1:5

2. dipping time: 2 minutes to 5 minutes

3. treatment temperature: room temperature

The silicon substrate achieved after the dipping includes a silicon substrate main body and a crystalline defect layer with a fourth surface on the silicon substrate main body, where the fourth surface is corresponding to the third surface before the dipping. Parameters of the silicon substrate include:

a thickness of the crystalline defect layer being less than 2 μm;

a surface roughness Rz of the silicon substrate of 1.7 μm; and

an average reflectivity being less than 25%.

A silicon substrate formed using conventional techniques may have a roughness of: Rmax of 1.88 μm, Rz of 1.71 μm and Ra of 0.256 μm. And a corresponding average reflectivity thereof is 26.43%.

Compared with the conventional techniques, the average reflectivity of the silicon substrate achieved after conducting the blasting treatment with the blasting material of the present disclosure is decreased by about 6.58%, while blasting treatment steps and production cycle are reduced. Furthermore, in some embodiments, no chemical corrosion solution needs to be consumed. Therefore, the present disclosure reduces production costs of a solar battery and is friendly to environment. It should be noted that, the silicon substrate achieved after conducting the blasting treatment but without conducting an extra chemical corrosion step may already meet the application requirements. However, to achieve a better effect, preferably, chemical corrosion treatment may be conducted to the silicon substrate achieved after conducting the blasting treatment.

By conducting the chemical treatment to the silicon substrate, the reflectivity thereof may be further reduced and a better effect may be achieved. Besides, the silicon raw piece produced by the crystal ribbon method has almost no mechanical damage layer formed on both two sides thereof. The SiC particles used for blasting have a relatively small particle diameter, so that, from the first surface of the silicon substrate, the mechanical damage layer is formed only with a small thickness and from the second surface, there is almost substantially no mechanical damage layer. Therefore, it is not necessary to use concentrated sulfuric acid for dipping and corrosion, since an acid solution made of HNO₃, HF and deionized water (or C₂H₄O₂) may be applicable. In the prior art, H₂O may be generated during corrosion treatment involving concentrated sulfuric acid, which may change the concentration of the solution. As a result, a new solution is required after about 16 thousands silicon substrates are treated. In the present disclosure, the acid solution used in the chemical treatment may treat over 300 thousands silicon substrates continuously. Besides, the corrosion step can also function as a cleaning step. Therefore, the present disclosure reduces processing time and cost and is friendly to environment.

### Exemplary Embodiment Three

A blasting material adapted to blast a surface of a silicon substrate is provided. The blasting material may include SiC particles. The blasting material may be used to blast the surface of the silicon substrate in a method described hereinafter. The method may include steps of:

Step 1: providing a silicon raw piece. The silicon raw piece is produced by applying a crystal ribbon method and includes a first surface and a second surface opposite to the first surface; and the first surface and the second surface substantially have almost no mechanical damage layer. Other physical parameters of the silicon raw piece may include:

a thickness of 170 μm; and

a surface reflectivity of 37.59%.

Step 2: under the action of compressed air, blasting the first surface of the silicon raw piece with the SiC particles.

1. Physical parameters of the SiC particles in the blasting material may include:

a median particle diameter of 14.650 μm;

an average sphericity of 0.875; and

a composition (weight percentage) of hexagonal SiC of 94.3%.

2. Treatment parameters of the blasting treatment may include: A compressed air pressure of 3.5 bars;

a blasting time of 12 seconds (a blasting frequency of 45 Hz and a speed of blasting displacement of 400 mm/min);

a distance between a nozzle and the silicon substrate of 6 centimeters; and

a blasting angle of 90°.

The silicon substrate achieved after conducting the blasting treatment includes: a silicon substrate main body and a mechanical damage layer with a third surface on the silicon substrate main body. The third surface is corresponding to the first surface before conducting the blasting treatment. The thickness, surface roughness and average reflectivity of the formed mechanical damage layer are measured as follows.

The thickness of the mechanical damage layer is within a range from about 3 μm to about 10 μm.

The surface roughness includes:

A first group: Rmax of 0.89 μm, Rz of 0.80 μm and Ra of 0.107 μm; and

A second group: Rmax of 1.26 μm, Rz of 1.03 μm and Ra of 0.121 μm.

The average reflectivity is 27.98%.

Step 3: dipping and corroding the third surface with an acid solution.

1. composition of the corrosion solution (volume ratio)

mixing 65% HNO₃ (volume percent), 40% HF (volume percent) and deionized water to obtain the acid corrosion solution,

wherein HNO₃:HF:deionized water=1:1:5

2. dipping time: 2 minutes to 5 minutes

3. treatment temperature: room temperature

The silicon substrate achieved after the dipping includes a silicon substrate main body and a crystalline defect layer with a fourth surface on the silicon substrate main body, where the fourth surface is corresponding to the third surface before the dipping. Parameters of the silicon substrate include:

a thickness of the crystalline defect layer less than 2 μm;

a surface roughness Rz of the silicon substrate of 1.7 μm; and an average reflectivity being less than 25%.

A silicon substrate formed using conventional techniques may have a roughness of: Rmax of 1.88 μm, Rz of 1.71 μm and Ra of 0.256 μm. And a corresponding average reflectivity thereof is 26.43%.

Compared with the conventional techniques, the average reflectivity of the silicon substrate achieved after conducting the blasting treatment with the blasting material of the present disclosure is decreased by about 5.19%, while blasting treatment steps and production cycle are reduced. Furthermore, in some embodiments, no chemical corrosion solution needs to be consumed. Therefore, the present disclosure reduces production costs of a solar battery and is friendly to environment. It should be noted that, the silicon substrate achieved after conducting the blasting treatment but without conducting an extra chemical corrosion step may already meet the application requirements. However, to achieve a better effect, preferably, chemical corrosion treatment may be conducted to the silicon substrate achieved after conducting the blasting treatment.

By conducting the chemical treatment to the silicon substrate, the reflectivity thereof may be further reduced and a better effect may be achieved. Besides, the silicon raw piece produced by the crystal ribbon method has almost no mechanical damage layer formed on both two sides thereof. The SiC particles used for blasting have a relatively small particle diameter, so that, from the first surface of the silicon substrate, the mechanical damage layer is formed only with a small thickness and from the second surface, there is almost substantially no mechanical damage layer. Therefore, it is not necessary to use concentrated sulfuric acid for dipping and corrosion, since an acid solution made of HNO₃, HF and deionized water (or C₂H₄O₂) may be applicable. In the prior art, H₂O may be generated during corrosion treatment involving concentrated sulfuric acid, which may change the concentration of the solution. As a result, a new solution is required after about 16 thousands silicon substrates are treated. In the present disclosure, the acid solution used in the chemical treatment may treat over 300 thousands silicon substrates continuously. Besides, the corrosion step can also function as a cleaning step. Therefore, the present disclosure reduces processing time and cost and is friendly to environment.

### Exemplary Embodiment Four

A blasting material adapted to blast a surface of a silicon substrate is provided. The blasting material may include SiC particles. The blasting material may be used to blast the surface of the silicon substrate in a method described hereinafter. The method may include steps of:

Step 1: providing a silicon raw piece. The silicon raw piece is produced by applying a crystal ribbon method and includes a first surface and a second surface opposite to the first surface; and the first surface and the second surface substantially have almost no mechanical damage layer. Other physical parameters of the silicon raw piece may include:

a thickness of 170 μm; and

a surface reflectivity of 37.59%.

Step 2: under the action of compressed air, blasting the first surface of the silicon raw piece with the SiC particles.

3. Physical parameters of the SiC particles in the blasting material may include:

a median particle diameter of 14.650 μm;

an average sphericity of 0.875; and

a composition (weight percentage) of hexagonal SiC of 94.3%.

4. Treatment parameters of the blasting treatment may include:

A compressed air pressure of 3.5 bars;

a blasting time of 10 seconds (a blasting frequency of 45Hz and a speed of blasting displacement of 600 mm/min);

a distance between a nozzle and the silicon substrate of 6 centimeters; and

a blasting angle of 90°.

The silicon substrate achieved after conducting the blasting treatment includes: a silicon substrate main body and a mechanical damage layer with a third surface on the silicon substrate main body. The third surface is corresponding to the first surface before conducting the blasting treatment. The thickness, surface roughness and average reflectivity of the formed mechanical damage layer are measured as follows.

The thickness of the mechanical damage layer is within a range from about 3 μm to about 10 μm.

The surface roughness includes:

A first group: Rmax of 1.18 μm, Rz of 0.97 μm and Ra of 0.092 μm; and

A second group: Rmax of 1.10 μ, Rz of 0.91 μm and Ra of 0.099 μm;

The average reflectivity is 29.37%.

Step 3: dipping and corroding the third surface with an acid solution.

1. composition of the corrosion solution (volume ratio)

mixing 65% HNO₃ (volume percent), 40% HF (volume percent) and deionized water to obtain the acid corrosion solution,

wherein HNO₃:HF:deionized water=1:1:5

2. dipping time: 2 minutes to 5 minutes

3. treatment temperature: room temperature

The silicon substrate achieved after the dipping includes a silicon substrate main body and a crystalline defect layer with a fourth surface on the silicon substrate main body, where the fourth surface is corresponding to the third surface before the dipping. Parameters of the silicon substrate include:

a thickness of the crystalline defect layer being less than 2 μm;

a surface roughness Rz of the silicon substrate of 1.7 μm; and

an average reflectivity being less than 25%.

A silicon substrate formed using conventional techniques may have a roughness of: Rmax of 1.88 μm, Rz of 1.71 μm and Ra of 0.256 μm. And a corresponding average reflectivity thereof is 26.43%.

Compared with the conventional techniques, the average reflectivity of the silicon substrate achieved after conducting the blasting treatment with the blasting material of the present disclosure is decreased by about 5.19%, while blasting treatment steps and production cycle are reduced. Furthermore, in some embodiments, no chemical corrosion solution needs to be consumed. Therefore, the present disclosure reduces production costs of a solar battery and is friendly to environment. It should be noted that, the silicon substrate achieved after conducting the blasting treatment but without conducting an extra chemical corrosion step may already meet the application requirements. However, to achieve a better effect, preferably, chemical corrosion treatment may be conducted to the silicon substrate achieved after conducting the blasting treatment.

By conducting the chemical treatment to the silicon substrate, the reflectivity thereof may be further reduced and a better effect may be achieved. Besides, the silicon raw piece produced by the crystal ribbon method has almost no mechanical damage layer formed on both two sides thereof. The SiC particles used for blasting have a relatively small particle diameter, so that, from the first surface of the silicon substrate, the mechanical damage layer is formed only with a small thickness and from the second surface, there is almost substantially no mechanical damage layer. Therefore, it is not necessary to use concentrated sulfuric acid for dipping and corrosion, since an acid solution made of HNO₃, HF and deionized water (or C₂H₄O₂) may be applicable. In the prior art, H₂O may be generated during corrosion treatment involving concentrated sulfuric acid, which may change the concentration of the solution. As a result, a new solution is required after about 16 thousands silicon substrates are treated. In the present disclosure, the acid solution used in the chemical treatment may treat over 300 thousands silicon substrates continuously. Besides, the corrosion step can also function as a cleaning step. Therefore, the present disclosure reduces processing time and cost and is friendly to environment.

Although the present disclosure has been disclosed as above with reference to preferred embodiments thereof but will not be limited thereto. Those skilled in the art can modify and vary the embodiments without departing from the spirit and scope of the present disclosure. Accordingly, without departing from the scope of the present invented technology scheme, whatever simple modification and equivalent variation belong to the protection range of the present invented technology scheme.

1. A blasting material adapted to blast a surface of a silicon substrate used in solar battery, comprising:
SiC particles having a median particle diameter within a range from about 1 μm to about 30 μm.

2. The blasting material according to claim 1, wherein the median particle diameter is within a range from about 6 μm to about 30 μm.

3. The blasting material according to claim 1, wherein the median particle diameter is within a range from about 10 μm to about 20 μm.

4. The blasting material according to claim 1, wherein the median particle diameter is within a range from about 6 μm to about 10 μm.

5. The blasting material according to claim 1, wherein the SiC particles have an average sphericity within a range from about 0.80 to about 0.94.

6. The blasting material according to claim 1, wherein the SiC particles have an average sphericity within a range from about 0.80 to about 0.92.

7. The blasting material according to claim 1, wherein the SiC particles comprise hexagonal SiC particles.

8. The blasting material according to claim 7, wherein a weight percentage of the hexagonal SiC particles relative to the SiC particles is within a range from about 70% to about 100%.

9. A method for producing a silicon substrate using a blasting material, comprising:
providing a silicon raw piece, the silicon raw piece comprising a first surface and a second surface opposite to the first surface; and
blasting the first surface of the silicon raw piece with SiC particles to form a mechanical damage layer having a third surface, where a median particle diameter of the SiC particles is within a range from about 1 μm to about 30 μm.

10. The method according to claim 9, wherein the silicon raw piece has a thickness within a range from about 120 μm to about 200 μm.

11. The method according to claim 9, wherein the silicon raw piece has a thickness within a range from about 160 μm to about 190 μm.

12. The method according to claim 9, further comprising:
partially removing the mechanical damage layer by performing a chemical treatment procedure on the third surface to create the silicon substrate.

13. The method according to claim 9, wherein the mechanical damage layer has a thickness within a range from about 3 μm to about 10 μm.

14. The method according to claim 9, wherein the mechanical damage layer has a thickness within a range from about 4 μm to about 8 μm.

15. The method according to claim 9, wherein the mechanical damage layer comprises a particle embedding layer, a mechanical layer, a stress layer and a crystalline defect layer positioned from outside to inside in sequence, wherein the particle embedding layer is located at the outermost surface of the silicon substrate.

16. The method according to claim 9, wherein the third surface has a reflectivity within a range from about 25% to about 30%.

17. The method according to claim 9, wherein a ten point height of irregularities Rz of the third surface is within a range from about 2 μm to about 4 μm.

18. The method according to claim 9, wherein a ten point height of irregularities Rz of the third surface is within a range from about 2 μm to about 2.5 μm.

19. The method according to claim 15, further comprising:
substantially removing an entirety of the particle embedding layer, the mechanical layer and the stress layer in the mechanical damage layer, and a part of the crystalline defect layer from the mechanical damage layer, by performing a chemical treatment procedure on the third surface.

20. The method according to claim 9, further comprising:
partially removing the mechanical damage layer by performing a chemical treatment procedure on the third surface, wherein the remaining mechanical damage layer has a thickness less than about 2 μm.

21. The method according to claim 9, wherein the silicon substrate is adapted for a silicon solar cell having a light receiving surface, the method further comprising:
partially removing the mechanical damage layer by performing a chemical treatment procedure on the third surface to obtain the silicon substrate, wherein the silicon substrate has a fourth surface corresponding to a light receiving surface of the silicon solar cell, and a reflectivity of the fourth surface is lower than the reflectivity of the third surface.

22. The method according to claim 19, wherein the chemical treatment procedure comprises etching the third surface with an acid solution.

23. The method according to claim 22, wherein the acid solution is at least one of a mixed solution of HNO₃, HF and deionized water, or a mixed solution of HNO₃, HF and C₂H₄O₂.

24. The method according to claim 23, wherein a combination of the HNO₃ and the HF have a volume concentration in the acid solution within a range from about 5% to about 20%, the deionized water has a volume concentration in the acid solution within a range from about 95% to about 80%, and a volume ratio of the HF to the HNO₃ is within a range from about 1 to about 15.

25. The method according to claim 23, wherein a combination of the HNO₃ and together with the HF have a volume concentration in the acid solution within a range from about 5% to about 20%, the C₂H₄O₂ has a volume concentration in the acid solution within a range from about 95% to about 80%, and a volume ratio of the HF to the HNO₃ is within a range from about 1 to about 15.

26. The method according to claim 21, wherein a ten point height of irregularities Rz of the fourth surface achieved after performing the chemical treatment procedure is greater than a ten point height of irregularities Rz of the third surface achieved after performing the blasting procedure.

27. The method according to claim 9, wherein the first surface of the silicon raw piece has a reflectivity within a range from about 30% to about 40%.

28. The method according to claim 27, wherein the third surface has a reflectivity within a range from about 25% to about 30%.

29. The method according to claim 28, further comprising:
partially removing the mechanical damage layer to create the silicon substrate having a fourth surface by performing a chemical treatment procedure on the third surface, wherein a reflectivity of the fourth surface is lower than the reflectivity of the third surface.

30. The method according to claim 9, wherein the third layer has a thickness within a range from about 3 μm to about 10 μm.

31. The method according to claim 30, further comprising:
partially removing the mechanical damage layer to create the silicon substrate having a fourth surface by performing a chemical treatment procedure on the third surface, wherein the remaining mechanical damage layer has a thickness less than about 2.5 μm.

32. The method according to claim 9, wherein a ten point height of irregularities Rz of the first surface is less than 0.5 μm.

33. The method according to claim 32, wherein a ten point height of irregularities Rz of the third surface is within a range from about 2 μm to about 4 μm.

34. The method according to claim 33, further comprising:
partially removing the mechanical damage layer to create the silicon substrate having a fourth surface by performing a chemical treatment procedure on the third surface, wherein a ten point height of irregularities Rz of the fourth surface is greater than the ten point height of irregularities Rz of the third surface.

35. The method according to claim 9, further comprising:
partially removing the mechanical damage layer to create the silicon substrate having a fourth surface by performing a chemical treatment procedure on the third surface with at least one of a mixed acid solution of HNO₃, HF and deionized water, or a mixed acid solution of HNO₃, HF and C₂H₄O₂.
